(19) United States
(12) Patent Application Publication
(10) Pub. No.: US 2024/0244943 A1
(43) Pub. Date: Jul. 18, 2024

(54) COMPOSITE QUANTUM-DOT OPTICAL FILM

(71) Applicant: UBRIGHT OPTRONICS CORPORATION, Taoyuan City (TW)

(72) Inventors: Chia-Yeh Miu, Taoyuan City (TW); Chia-Jung Chiang, Taoyuan City (TW); TING YING LIU, Taoyuan City (TW); Lung-Pin Hsin, Taoyuan City (TW); Jeffrey Wu, Taoyuan City (TW); Hui-Yong Chen, Taoyuan City (TW)

(21) Appl. No.: 18/415,689

(22) Filed: Jan. 18, 2024

Related U.S. Application Data
(60) Provisional application No. 63/439,844, filed on Jan. 18, 2023.

(51) Int. Cl. H10K 77/10; H10K 50/115; H10K 85/10

(52) U.S. Cl. CPC H10K 77/10; H10K 50/115; H10K 85/141

(57) ABSTRACT

A composite quantum-dot optical film comprises a quantum-dot layer and a substrate, wherein the substrate comprises a unitary body formed by a first material, wherein a plurality of particles are disposed in the unitary body that encapsulates an outer surface of a first particle with said outer surface of the first particle being located above the top surface of the unitary body, wherein the substrate is disposed over the quantum-dot layer.

### CROSS-REFERENCE TO RELATED APPLICATIONS

This application claims the benefit of U.S. provisional patent application No. 63/439,844, filed on Jan. 18, 2023, which is hereby incorporated herein by reference.

### BACKGROUND OF THE INVENTION

### 1. Field of the Invention

The present invention relates to an optical film, and more particularly to a composite quantum-dot optical film.

### 2. Description of Related Art

Conventional quantum-dot optical film often has an adhesion problem with other optical layers. Additionally, the surface of quantum-dot optical film can be scratched easily. Additionally, the trend of slimming down optical modules affects the compatibility and assembly yield of optical films within compressed modules. This, in turn, influences customers' willingness to adopt mid-to-high-end mainstream models. Therefore, how quantum-dot optical films respond to the trend of slimming down future display products is crucial.

Accordingly, the present invention proposes a new solution to overcome the disadvantages as mentioned above.

### SUMMARY OF THE INVENTION

One objective of the present invention is to develop a substrate that has a roughened surface exhibiting excellent antistatic and scratch resistance between optical film layers.

One objective of the present invention is to develop a substrate that has a roughened surface on one side of the substrate that exhibits excellent antistatic and scratch resistance between optical film layers, on the other side of the substrate, a gas and moisture barrier layer is formed through a subsequent vapor deposition or sputtering process.

One objective of the present invention is to develop a composite quantum-dot optical film comprising a substrate disposed on a quantum-dot optical film, wherein the substrate has a roughened surface on one side of the substrate exhibiting excellent antistatic and scratch resistance between optical film layers, on the other side of the substrate, a gas and moisture barrier layer is formed through a subsequent vapor deposition or sputtering process.

In one embodiment, the present invention discloses an optical film comprising: a first substrate, wherein the first substrate comprises a unitary body formed by a first material, wherein a first plurality of particles are disposed in the unitary body, wherein the unitary body comprises a top surface between a first particle and a second particle of the first plurality of particles, wherein the unitary body encapsulates an outer surface of the first particle with said outer surface of the first particle being located above the top surface of the unitary body.

In one embodiment, the present invention discloses a composite optical film comprising: an optical layer; and a first substrate, wherein the first substrate comprises a unitary body formed by a first material, wherein a first plurality of particles are disposed in the unitary body, wherein the unitary body comprises a top surface between a first particle and a second particle of the first plurality of particles, wherein the unitary body encapsulates an outer surface of the first particle with said outer surface of the first particle being located above the top surface of the unitary body, wherein the first substrate is disposed over a top surface of the optical layer.

In one embodiment, the present invention discloses a composite quantum-dot optical film, wherein the composite quantum-dot optical film comprises: a quantum-dot layer comprising a binder and a plurality of quantum dots dispersed in the binder; and a first substrate, being made of a first material, wherein a first plurality of particles are disposed in the first substrate, wherein the first material forms a unitary body that encapsulates the entire outer surface of a first particle with at least one portion of the first particle protruding on the a top surface of the unitary body of the first substrate, wherein the first substrate is disposed over a top surface of the quantum-dot layer.

In one embodiment, the entire first particle is located above the top surface of the unitary body of the first substrate with no portion of the first particle being located below the top surface of the unitary body of the first substrate.

In one embodiment, a first portion of the first particle is located above the top surface of the unitary body of the first substrate, and a second portion of the first particle is located below the top surface of the unitary body of the first substrate.

In one embodiment, the outer surface of the first particle has a roughed surface.

In one embodiment, a first bottom of the first substrate is laminated on a top surface of the quantum-dot layer.

In one embodiment, a first inorganic compound is evaporated or sputtered on a first bottom of the first substrate, wherein the first bottom of the first substrate is laminated on a top surface of the quantum-dot layer.

The detailed technology and above-preferred embodiments implemented for the present invention are described in the following paragraphs accompanying the appended drawings for people skilled in this field to well appreciate the features of the claimed invention.

### BRIEF DESCRIPTION OF THE DRAWINGS

The foregoing aspects and many of the accompanying advantages of this invention will become more readily appreciated as the same becomes better understood by reference to the following detailed description when taken in conjunction with the accompanying drawings, wherein:

FIG. 1A illustrates a schematic cross-sectional view of a composite quantum-dot optical film;

FIG. 1B illustrates an enlarged cross-sectional view of the first substrate 250 of the composite quantum-dot optical film in FIG. 1A according to one embodiment of the present invention;

FIG. 1C illustrates an enlarged cross-sectional view of the first substrate 250 of the composite quantum-dot optical film in FIG. 1A according to one embodiment of the present invention;

FIG. 1D illustrates an enlarged cross-sectional view of the second substrate 260 of the composite quantum-dot optical film in FIG. 1A according to one embodiment of the present invention;

FIG. 1E illustrates an enlarged cross-sectional view of the second substrate 260 of the composite quantum-dot optical film in FIG. 1A according to one embodiment of the present invention;

FIG. 2 illustrates a schematic cross-sectional view of a composite quantum-dot optical film according to one embodiment of the present invention;

FIG. 3 illustrates a method to form a composite quantum-dot optical film according to one embodiment of the present invention;

FIG. 4 illustrates a chart to compare the present invention with the conventional technology.

### DETAILED DESCRIPTION OF THE ILLUSTRATED EMBODIMENTS

The detailed explanation of the present invention is described as follows. The described preferred embodiments are presented for purposes of illustrations and descriptions, and they are not intended to limit the scope of the present invention.

The substrate of this invention not only can address the barrier properties in the optical film industry but also enhance the scratch resistance of the quantum dot film. Simultaneously, when used in conjunction with other optical films, it can prevent interference issues caused by adsorption or sticking, resolving one of the anomalies encountered in the panel industry related to poor image quality.

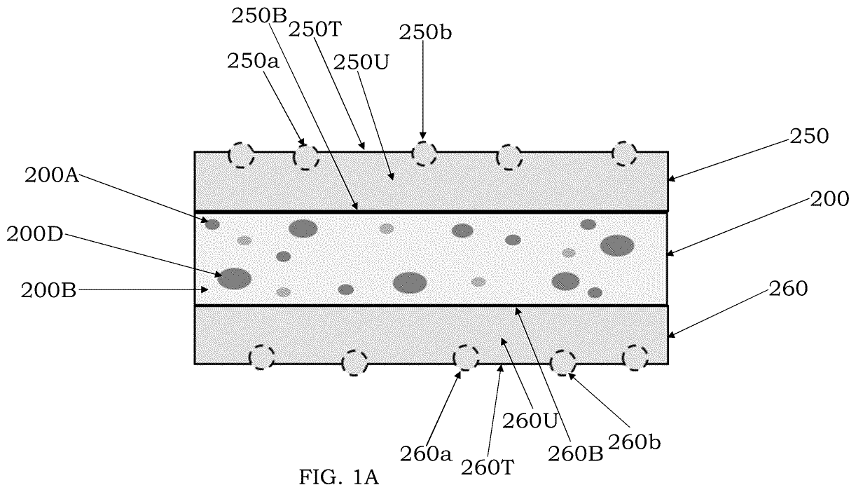

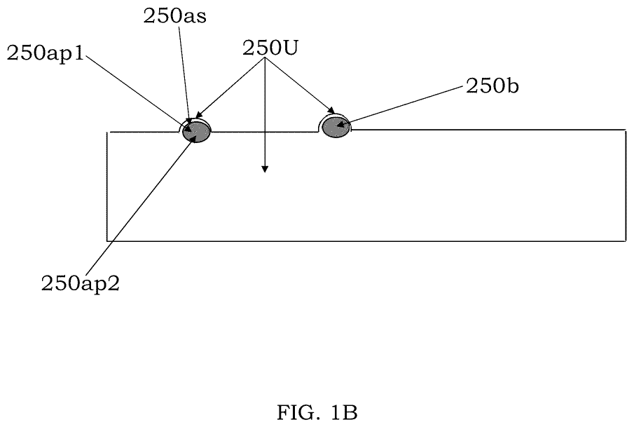

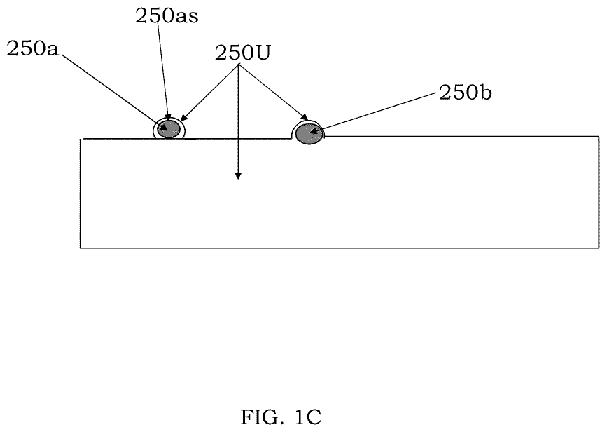

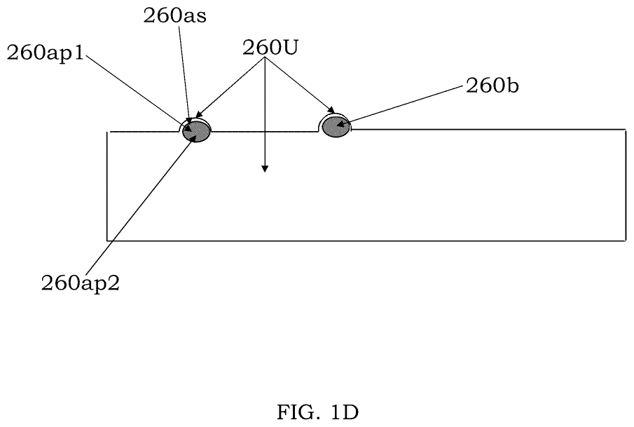

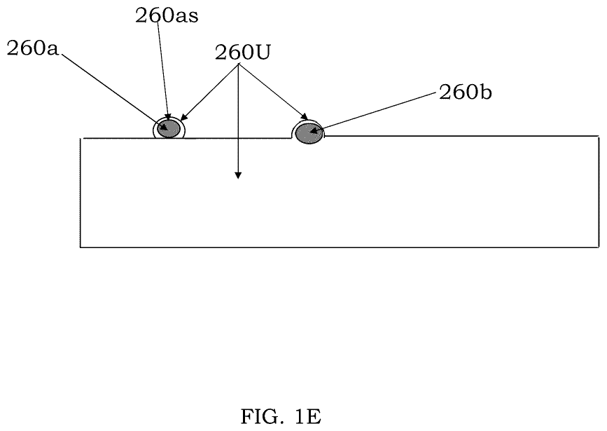

FIG. 1A illustrates a schematic cross-sectional view of the composite quantum-dot optical film according to one embodiment of the present invention, FIG. 1B illustrates an enlarged view of the cross-sectional view of the composite quantum-dot optical film according to one embodiment of the present invention. Please refer to FIG. 1A and FIG. 1B, wherein the composite quantum-dot optical film comprises: a quantum-dot layer 200 comprising a binder 200B and a plurality of quantum dots 200A dispersed in the binder 200B; and a first substrate 250, wherein the first substrate 250 is formed by a first material, wherein a first plurality of particles 250a, 250b are disposed in the first substrate 250, wherein the first substrate 250 comprises a top surface 250T between a first particle 250a and a second particle 250b of the first plurality of particles 250a, 250b, wherein the first material forms the top surface 250T of the first substrate 250 and encapsulates an outer surface 250as of the first particle 250a with said outer surface 250as of the first particle 250a being located above the top surface 250T of the first substrate 250, as shown in FIG. 1B, wherein the first substrate 250 is disposed over the quantum-dot layer 200 as shown in FIG. 1A.

FIG. 1A illustrates a schematic cross-sectional view of the composite quantum-dot optical film according to one embodiment of the present invention, FIG. 1B illustrates an enlarged view of the cross-sectional view of the composite quantum-dot optical film according to one embodiment of the present invention. Please refer to FIG. 1A and FIG. 1B, wherein the composite quantum-dot optical film comprises: a quantum-dot layer 200 comprising a binder 200B and a plurality of quantum dots 200A dispersed in the binder 200B; and a first substrate 250, wherein the first substrate 250 comprises a unitary body 250U formed by a first material, wherein a first plurality of particles 250a, 250b are disposed in the unitary body 250U, wherein the unitary body 250U comprises a top surface 250T between a first particle 250a and a second particle 250b of the first plurality of particles 250a, 250b, wherein the unitary body 250U encapsulates an outer surface 250as of the first particle 250a with said outer surface 250as of the first particle 250a being located above the top surface 250T of the unitary body 250U, as shown in FIG. 1B, wherein the first substrate 250 is disposed over the quantum-dot layer 200 as shown in FIG. 1A.

In one embodiment, the first substrate 250 is a first base film.

In one embodiment, the first particle 250a comprises silica.

In one embodiment, the first particle 250a consists of silica.

In one embodiment, the first material comprises a polymer.

In one embodiment, the first material consists of polymer.

In one embodiment, the first material comprises PET.

In one embodiment, the first material consists of PET.

In one embodiment, as shown in FIG. 1B, a first portion 250ap1 of the first particle 250a is located above the top surface 250T of the unitary body 250U, and a second portion 250ap2 of the first particle 250a is located below the top surface 250T of the unitary body 250U.

In one embodiment, as shown in FIG. 1C, the entire first particle 250a is located above the top surface 250T of the unitary body 250U with no portion of the first particle 250a being located below the top surface 250T of the unitary body 250U of the first substrate 250.

In one embodiment, as shown in FIG. 1C, the entire outer surface 250s of the first particle 250a is encapsulated by the unitary body 250U.

In one embodiment, the outer surface of the first particle has a roughed surface.

In one embodiment, a first bottom of the first substrate 250 is laminated on a top surface of the quantum-dot layer 200.

In one embodiment, as shown in FIG. 1A and FIG. 1D, the second substrate 260 comprises a unitary body 260U formed by a second material, wherein a second plurality of particles 260a, 260b are disposed in the unitary body 260U, wherein the unitary body 260U comprises a top surface 260T between a third particle 260a and a fourth particle 260b of the second plurality of particles 260a, 260b, wherein the unitary body 260U encapsulates an outer surface 260as of the first particle 260a with said outer surface 260as of the third particle 260a being located above the top surface 260T of the unitary body 260U, wherein the second substrate 260 is disposed over the bottom surface of the quantum-dot layer 200.

In one embodiment, as shown in FIG. 1D, a first portion 260ap1 of the third particle 260a is located above the top surface 260T of the unitary body 260U, and a second portion 260ap2 of the third particle 260a is located below the top surface 260T of the unitary body 260U.

In one embodiment, as shown in FIG. 1E, the entire third particle 260a is located above the top surface 260T of the unitary body 260U with no portion of the third particle 260a being located below the top surface 260T of the unitary body 260U.

In one embodiment, the second bottom surface 260B is laminated on a bottom surface of the quantum-dot layer 200.

In one embodiment, the second substrate 260 is a second base film.

In one embodiment, the third particle 260a comprises silica.

In one embodiment, the third particle 260a consists of silica.

In one embodiment, the second material comprises a polymer.

In one embodiment, the second material consists of polymer.

In one embodiment, the second material comprises PET.

In one embodiment, the second material consists of PET.

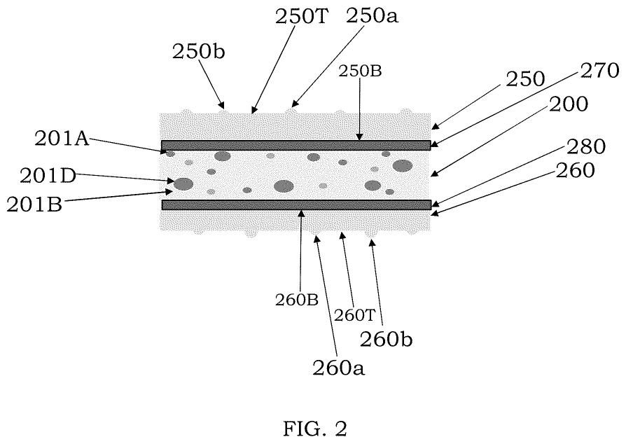

In one embodiment, as shown in FIG. 2, a first inorganic compound is evaporated or sputtered on a first bottom surface 250B of the first substrate 250 to form a barrier layer 270, wherein the barrier layer 270 is laminated on the top surface of the quantum-dot layer 200.

In one embodiment, as shown in FIG. 2, a second inorganic compound is evaporated or sputtered on the second bottom surface 260B of the second substrate 260 to form a barrier layer 280, wherein the barrier layer 280 is laminated on a bottom surface of the quantum-dot layer 200.

In one embodiment, the first inorganic compound is capable of being water-resistant and oxygen-resistant.

In one embodiment, the second inorganic compound is capable of being water-resistant and oxygen-resistant.

In one embodiment, as shown in FIG. 2, a second inorganic compound is evaporated or sputtered on a bottom of the second substrate 260 to form a barrier layer 280, wherein the bottom of the barrier layer 280 is laminated on the bottom surface of the quantum-dot layer 200.

In one embodiment, as shown in FIG. 1A, a composite quantum-dot optical film is disclosed, wherein the composite quantum-dot optical film comprises: a quantum-dot layer 200 comprising a binder and a plurality of quantum dots 200A dispersed in the binder 200B;

and a first substrate 250, wherein the first substrate 250 is formed by a first material, wherein a first plurality of particles 250a, 250b are disposed in the first substrate 250, wherein the first substrate 250 comprises a top surface 250T between a first particle 250a and a second particle 250b of the first plurality of particles, wherein the first material encapsulates an outer surface 250as of the first particle 250a with said outer surface 250as of the first particle 250a being located above the top surface 250T of the first substrate 250, wherein the first substrate 250 is disposed over a top surface of the quantum-dot layer 200.

In one embodiment, as shown in FIG. 2, a first inorganic compound is evaporated or sputtered on a bottom of the first substrate to form a first barrier layer 270, wherein the first barrier layer 270 is laminated on a top surface of the quantum-dot layer 200.

In one embodiment, as shown in FIG. 1B, a first portion 250ap1 of the first particle 250a is located above the top surface 250T of the unitary body 250U, and a second portion 250ap2 of the first particle 250a is located below the top surface 250T of the unitary body 250U.

In one embodiment, a thickness of the first substrate is in a range of 12-125 um.

In one embodiment, a thickness of the composite quantum-dot optical film is in a range of 36-350 um.

In one embodiment, the plurality of particles comprise at least one of the organic particles: PMMA, PS, or Melamine.

In one embodiment, the plurality of particles comprise at least one of the inorganic particles: Silicon, SiO₂, TiO₂, CaCO₃, Al₂O₃, ZrO₂.

FIG. 1B illustrates an enlarged view of the cross-sectional view of the composite optical film according to one embodiment of the present invention. Please refer to FIG. 1B, wherein the composite optical film comprises: a first substrate 250, wherein the first substrate 250 comprises a unitary body 250U formed by a first material, wherein a first plurality of particles 250a, 250b are disposed in the unitary body 250U, wherein the unitary body 250U comprises a top surface 250T between a first particle 250a and a second particle 250b of the first plurality of particles 250a, 250b, wherein the unitary body 250U encapsulates an outer surface 250as of the first particle 250a with said outer surface 250as of the first particle 250a being located above the top surface 250T of the unitary body 250U.

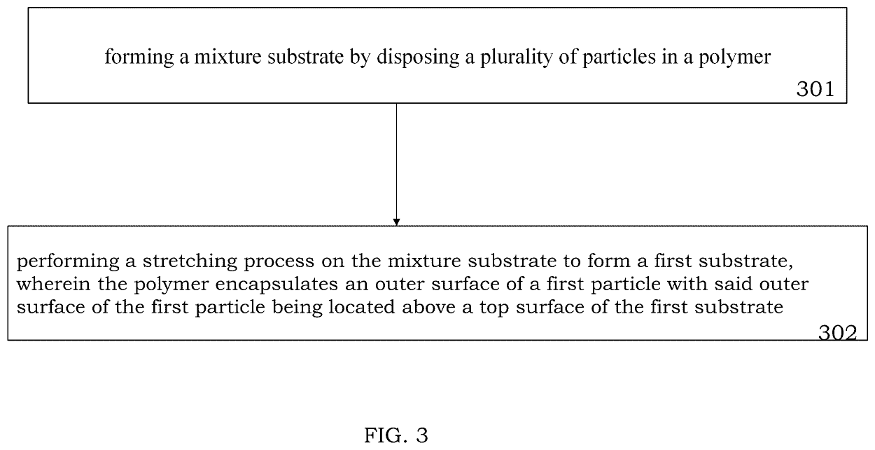

FIG. 3 illustrates a method to form a composite quantum-dot optical film according to one embodiment of the present invention, wherein the method comprises: step 301: forming a mixture substrate by disposing a plurality of particles in a polymer; step 302: performing a stretching process on the mixture substrate to form a first substrate, wherein the polymer encapsulates an outer surface of a first particle with said outer surface of the first particle being located above a top surface of the first substrate.

In one embodiment, the mixture substrate is formed by performing an injection molding with a mixture formed by adding the plurality of particles into said polymer, and the plurality of particles are caused to protrude on a top surface of the first substrate during the stretching process on the mixture substrate.

In one embodiment, the first particle comprises silica.

In one embodiment, the first particle consists of silica.

In one embodiment, the polymer comprises PET.

In one embodiment, the polymer consists of PET.

In one embodiment, the method further comprises laminating the first bottom of the first substrate on a top surface of a quantum-dot layer.

In one embodiment, the method further comprises forming a barrier layer on a first bottom of the first substrate by evaporating or sputtering an inorganic compound on the first bottom of the first substrate to form the barrier layer.

In one embodiment, the method further comprises laminating the first bottom of the barrier layer on the top surface of the quantum-dot layer.

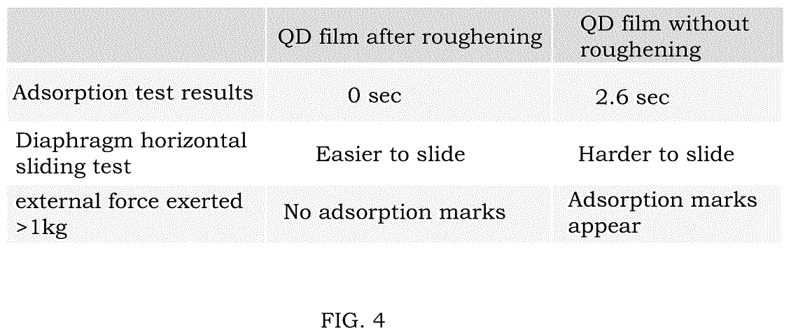

FIG. 4 illustrates a chart to compare the present invention with the conventional technology. Under the condition of a weight load of greater than 1 Kg, the QD film (roughened) was tested under high temperature and pressure with a light guide plate. There was no adsorption of the light guide plate on the bottom surface, and there were no adsorption indentations of heavy objects. The adsorption state of QD film (non-roughened) will recover in about 2˜3 seconds when paired with a light guide plate. According to the diaphragm sliding test, the roughened QD film moves more smoothly, while the non-roughened QD film moves more astringently, indicating that the roughening effect still achieves the anti-adsorption effect.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A composite quantum-dot optical film comprising:
a quantum-dot layer comprising a binder and a plurality of quantum dots dispersed in the binder; and
a first substrate, wherein the first substrate comprises a first unitary body formed by a first material, wherein a first plurality of particles are disposed in the first unitary body, wherein the first unitary body comprises a top surface between a first particle and a second particle of the first plurality of particles, wherein the first unitary body encapsulates an outer surface of the first particle with said outer surface of the first particle being located above the top surface of the first unitary body, wherein the first substrate is disposed over a top surface of the quantum-dot layer.

2. The composite quantum-dot optical film according to claim 1, wherein a first portion of the first particle is located above the top surface of the first unitary body, and a second portion of the first particle is located below the top surface of the first unitary body.

3. The composite quantum-dot optical film according to claim 1, wherein the entire first particle is located above the top surface of the first unitary body with no portion of the first particle being located below the top surface of the first unitary body of the first substrate.

4. The composite quantum-dot optical film according to claim 1, wherein the entire outer surface of the first particle is encapsulated by the first unitary body.

5. The composite quantum-dot optical film according to claim 1, wherein said outer surface of the first particle has a roughed surface.

6. The composite quantum-dot optical film according to claim 1, wherein a bottom of the first substrate is laminated on a top surface of the quantum-dot layer.

7. The composite quantum-dot optical film according to claim 1, wherein a first inorganic compound is evaporated or sputtered on a bottom of the first substrate to form a first barrier layer, wherein the first barrier layer is laminated on a top surface of the quantum-dot layer.

8. The composite quantum-dot optical film according to claim 1, wherein the first material comprises PET.

9. The composite quantum-dot optical film according to claim 1, wherein the first material consists of PET.

10. The composite quantum-dot optical film according to claim 7, wherein the first inorganic compound is capable of being water-resistant and oxygen-resistant.

11. The composite quantum-dot optical film according to claim 1, wherein a thickness of the first substrate is in a range of 12-125 um.

12. The composite quantum-dot optical film according to claim 1, further comprising a second substrate, wherein the second substrate comprises a second unitary body formed by a second material, wherein a second plurality of particles are disposed in the second unitary body, wherein the second unitary body comprises a top surface between a third particle and a fourth particle of the second plurality of particles, wherein the second unitary body encapsulates an outer surface of the third particle with said outer surface of the third particle being located above the top surface of the second unitary body, wherein the second substrate is disposed over a bottom surface of the quantum-dot layer.

13. The composite quantum-dot optical film according to claim 12, wherein a second inorganic compound is evaporated or sputtered on a bottom of the second substrate to form a second barrier layer, wherein the second barrier layer is laminated on the bottom surface of the quantum-dot layer.

14. The composite quantum-dot optical film according to claim 1, wherein the first particle comprises silica.

15. The composite quantum-dot optical film according to claim 1, wherein the first particle consists of silica.

16. The composite quantum-dot optical film according to claim 1, wherein the first particle comprises at least one of the organic particles: PMMA, PS, or Melamine.

17. The composite quantum-dot optical film according to claim 1, wherein the first particle comprises at least one of the inorganic particles: Silicon, SiO₂, TiO₂, CaCO₃, Al₂O₃, ZrO₂.

18. A composite quantum-dot optical film comprising:
a quantum-dot layer comprising a binder and a plurality of quantum dots dispersed in the binder; and
a first substrate, wherein the first substrate is formed by a first material, wherein a first plurality of particles are disposed in the first substrate, wherein the first substrate comprises a top surface between a first particle and a second particle of the first plurality of particles, wherein the first material encapsulates an outer surface of the first particle with said outer surface of the first particle being located above the top surface of the first substrate, wherein the first substrate is disposed over a top surface of the quantum-dot layer.

19. The composite quantum-dot optical film according to claim 18, wherein a first inorganic compound is evaporated or sputtered on a bottom of the first substrate to form a first barrier layer, wherein the first barrier layer is laminated on a top surface of the quantum-dot layer.

20. The composite quantum-dot optical film according to claim 18, wherein a first portion of the first particle is located above the top surface of the first substrate, and a second portion of the first particle is located below the top surface of the first substrate.
